(19) United States
(12) Patent Application Publication
(10) Pub. No.: US 2007/0206247 A1
(43) Pub. Date: Sep. 6, 2007

(54) System, apparatus, and method for managing preloaded digital files for preview on a digital media playback apparatus

(75) Inventor: Joshua D. Kaplan, Berkeley, CA (US)

Correspondence Address: Dergosits & Noah LLP, Suite 1450, Four Embarcadero Center, San Francisco, CA, 94111, US

(73) Assignee: Intouch Group, Inc.

(21) Appl. No.: 11/365,545

(22) Filed: Mar. 1, 2006

(51) Int. Cl. G03F 3/10

(52) U.S. Cl. 358/527

(57) ABSTRACT

A portable digital media playback apparatus is disclosed. The device comes preloaded with a large number of digital media files for preview. After preview, the files are tagged with information that indicate that the user wishes to purchase the digital media file or purchase certain digital rights associated with the digital media file, such as for example, rental to play the media three times. When the portable device is synched back up with a library of digital media files available for purchase or rental, the files designated for purchase are downloaded to the portable device and files designated to be deleted are deleted from the portable device. In one embodiment, a user profile is created and includes a record of user events relating to the digital media files previewed or deleted or selected for purchase. The user profile is then provided to the content provider to compare it with the characteristics of additional digital media files available for preview. The content provider adopts a set of criteria for matches and with this policy or business rule creates a list of additional digital media files that are compatible with the user and which will be pushed down to the portable device the next time that the user synchs up. The user profile information from multiple users can be aggregated and stripped of the personal information to deliver valuable market research data to participants in the digital media marketplace.

### TECHNICAL FIELD

The present invention relates generally to a system, apparatus, and method for providing preloaded digital files for preview on a digital media playback apparatus. More particularly, the present invention relates to a digital media playback apparatus having previewable digital files which are preloaded onto the digital media playback apparatus during manufacture or at the purchase location.

### BACKGROUND OF THE INVENTION

Portable digital media players have gained significant popularity. For example, the Apple iPod™ is a portable music player that has changed the way most people view music playback. The portable digital media players typically have large amounts of storage capacity (e.g., 512 kilobits to 60 gigabits). However, it is believed that over 50% of that capacity is not used because of various factors. For example, users may not have time to load all of their own music, or the method of converting normal content to compressed digital files (e.g., mp3, mpeg, avi, etc.) may be viewed as too cumbersome or time-consuming.

Furthermore, the digital media (e.g., music, video, or text) is typically placed onto the portable digital media players using a computer by either (i) converting media (e.g., compact discs (“CDs”) or digital video discs (“DVDs”)) to the appropriate compressed digital file or (ii) purchasing a compressed digital file from an online provider, e.g., the iTunes™ web site. In order to purchase a digital file from an online provider, the user typically reviews various digital media on the web site of the online content provider, and then purchases the digital media for download onto the computer. The digital media then has to be transferred to the portable digital media player by using software on the computer that is compatible with the portable player. This can be a cumbersome and time-consuming process.

In addition, due to stringent Digital Rights Management requirements, the content copyright owners require that the end user possess all of the rights before the user downloads the digital media files onto any device.

Accordingly, there is a need to more efficiently utilize the free space available on portable digital media players. There is also a need to provide a more streamlined process for reviewing and purchasing digital media files. There is also a need for a platform for digital content providers to deliver personalized content to the end user, based upon user behavior and selections.

### SUMMARY OF THE INVENTION

One object of the invention is to efficiently utilize the free space available on portable digital media players by preloading the device with digital media files for preview at the time of manufacture or purchase of the device. Another object of the invention is to provide a streamlined process for previewing and purchasing digital media files.

It is believed that the apparatus, system and method of the present invention allow the following benefits. Preloading the playback apparatus effectively utilizes empty space on the storage medium of the digital playback device. Furthermore, preloading the playback apparatus allows the user to be exposed to new content directly from the playback apparatus, thereby removing the requirement of going online and spending time clicking on and downloading previews to the user's computer via the Internet. Further, when the digital playback apparatus is portable, users are free to utilize the large amount of free time available away from home to preview the digital media files in their own privacy, as the devices have personal headphones as opposed to loudspeakers.

One aspect of the present invention is to have huge amounts of digital products pre-loaded on various devices (books, movies, software, music) and allow people to preview, rate the items, indicate a ‘purchase’ or ‘delete’ response located on the device, and then, when the user re-synchs, items purchased are then fully downloaded, or licensed according to the digital rights (including rental) while items reviewed and rated negatively are deleted from the device.

According to one embodiment of the present invention, a portable digital media playback apparatus is provided having a large number of preloaded digital media files for preview by a user. The playback apparatus has an operating system for operating the portable digital media playback apparatus with executable software code for (1) tagging at least one preloaded digital media file with information that identifies that file as a file for purchase or rental by the user; (2) communicating the information concerning the tagged file to a computer separate from the portable digital media playback apparatus; and, (3) deleting digital media files from the portable digital media playback apparatus when a delete command is received from the separate computer for a particular digital media file. The playback apparatus also has a communication port allowing the portable digital media playback apparatus to communicate with the separate computer. The playback apparatus further includes a data storage device preloaded during manufacture of the playback apparatus, or at the time of purchase, with at least about 128 KB of digital media files for preview by the user, the digital media files optionally having limited usage rights. The playback apparatus has a user interface associated with the portable digital media playback apparatus operating system to direct the operating system to tag one or more digital media files with information that identifies that file as a file for purchase or rental by the user. The playback apparatus can be optionally pre-loaded with digital media files for preview at a level of between about 25% and 100% of the playback apparatus data storage.

One of the methods of the present invention is a method for providing and managing large numbers of digital media files on a portable digital media playback apparatus for preview and purchase or rental by a user, for use in conjunction with a computer separate from the portable digital media playback apparatus. The method involves (1) providing a portable digital media playback apparatus having an operating system including executable code (a) for tagging at least one of the digital media files with information that identifies that file as a file for purchase or rental; (b) communicating information concerning the tagged file to the computer separate from the portable digital media playback apparatus; and (c) for deleting digital media files from the portable digital media player apparatus when a delete command is received from the separate computer directed to a particular digital media file. The playback device also has a communication port allowing the portable digital media playback apparatus to communicate with the separate computer, and, a data storage device. According to the method, another step is (2) providing on the portable digital media player apparatus storage device at the time of purchase at least about 128 KB of digital media files for preview by the user, the optional files having limited usage rights. The device also is provided with a user interface associated with the portable digital media playback apparatus operating system to tag one or more digital media files with information that identifies that file as a file for purchase or rental by the user. In response to the information that identifies that file as a file for purchase or rental, the method provides on the portable digital media playback device a digital media file that possesses the appropriate digital rights corresponding to the tagged file information. As an optional part of this method, the user is able to rate the pre-loaded digital media files, possibly using a rating system of 1 as the worst and 5 as the best. This rating information can be captured as part of the user profile and be used as part of the data available to the content provider to make recommendations to the user of additional digital media files for preview.

In another embodiment of the present invention, a portable digital media playback apparatus could be preloaded with a large number of digital media files at the time of manufacture or purchase. The device has (1) storage media for storing preloaded digital media files for preview by a user; (2) a large number of preloaded digital media files stored in said storage media and available for preview by the user; (3) first executable software code for deleting at least one preloaded digital media file from the portable digital media playback apparatus storage media when a delete command is received; (4) second executable software code for tagging at least one preloaded digital media file with information that identifies the file as a file for purchase or rental by the user; (5) a first user interface allowing the user to issue delete commands to the first executable software code to delete preloaded digital media files from the storage media; (6) a second user interface allowing the user, through operation of the second executable software code, to tag at least one preloaded digital media file with information that identifies that file as a file for purchase or rental by the user; (7) a communications port between the portable digital media playback apparatus and the separate computer; and, (8) third executable software code for allowing the portable digital media playback apparatus to issue a request to the separate computer for the appropriate digital rights for the at least one digital media file corresponding to the information that identified the file as a file for purchase or rental.

In another embodiment of the present invention, in a system comprising a portable digital media playback apparatus loaded with a large number of digital media files for preview by a user of the portable digital media playback apparatus, a separate computer and a content provider server, there is a method for delivering recommended digital media files for preview on the portable digital media playback apparatus. The method comprises the following steps: (1) on the portable digital media playback apparatus, creating a user profile based upon user interactions with the digital media files for preview loaded on the portable digital media playback apparatus; (2) transmitting the user profile from the portable digital media playback apparatus to the separate computer through a communications port on the portable digital media playback apparatus; (3) transmitting the user profile from the separate computer to the content provider server; (4) at said content-provider server, comparing characteristics of digital media files available for preview with the user profile; (5) transmitting from the content provider server to the separate computer a plurality of digital media files, optionally with limited usage rights, for preview that match at least one aspect of the user profile; and, (6) transmitting from the separate computer the plurality of digital media files, optionally with limited usage rights, for preview that match at least one aspect of the user profile to the portable digital media playback apparatus.

In connection with this embodiment, the user profile may also contain demographic information about the user, or rating information entered by the user comprising the user's rating of the digital media files that the user has already previewed, for example scoring a one (1) for the worst file and a five (5) for the best file.

It is also considered within the scope of this invention to create the user profile on the separate computer, or on the content server computer when the portable device is synched with the separate computer. This user profile captures user activities and then enables the recommendation of additional digital media files for preview.

It is also considered within the scope of the present invention to configure a system without the separate computer. In this instance, the portable playback apparatus would have to possess the ability to connect directly to the Internet using Internet browsing software.

### BRIEF DESCRIPTION OF THE FIGURES

FIG. 1 is a block diagram of one of the embodiments of the present invention involving a portable playback apparatus, a separate computer and a content server.

FIG. 2 is a block diagram of another embodiment of the present invention in which the separate computer of FIG. 1 is eliminated.

FIG. 3 is a block flow chart of one of the methods of the present invention for preloading a portable apparatus, allowing the user to tag files for purchase or deletion, and then providing the purchased file or deleting the file designated for deletion.

FIG. 4 is a block flow diagram for a method of providing additional recommended digital media files to the user for preview based upon the user's previous selections and actions on the portable apparatus.

### DETAILED DESCRIPTION OF THE INVENTION

The term “portable digital media playback apparatus,” as used herein, means any handheld apparatus that provides playback of digital files. Nonlimiting examples include handheld music players (e.g., the iPod Nano, and other products in the iPod product line as well as the Zen Player), handheld video players (e.g., the iPod), cell phones, personal digital assistants (“PDA”), and any other flash memory based or portable hard drive based handheld devices (such as those currently marketed by SanDisk) having digital media playback capabilities.

The term “digital media,” as used herein, means electronically-represented data that provides content in audio or visual or audio and visual forms. Nonlimiting examples of digital media include text (e.g., books), graphics, photographs, still frames from video, schematics, maps, music, voice recordings, spoken word, and movies or video-based content.

The term “digital media management software,” as used herein, means a computer executable program that manages digital media files. The media management software can be resident on a personal computer (e.g., iTunes), wherein a portable digital playback apparatus (e.g., iPod), defined below, can communicate with the management software for downloading digital media files to the portable digital playback apparatus. Alternatively, the media management software can be resident on the portable digital playback apparatus (e.g., a cell phone or PDA). Example of digital media management software are Apple's iTunes 6.0, Rhapsody, Napster, Real Player and other commercially available software for the loading, deleting, storage, organization and playback of digital media files.

The term “digital rights management system,” as used herein, means a system that keeps track of the usage rights of a digital media file. Digital Rights Management is the umbrella term referring to any of several technologies to enforce pre-defined policies controlling access to software, music, movies or other digital data. In more technical terms, DRM handles the description, layering, analysis, valuation, trading and monitoring of the rights held over a digital work. See http://en.wikipedia.org/wiki/Digital-rights-management, the disclosure of which is incorporated by reference. See also, Windows Media Digital Rights Management (DRM), a platform to protect content for playback on computers, portable devices, and network devices. See http://www.microsoft.com/windows/windowsmedia/drm/default.mspx. See also http://www.activeinternet.com/drm/?GoogleDRM. For example, the digital rights management system can include hardware and/or software to delete digital media files from data storage according to the usage rights (e.g., after 14 days, or 3 previews). The digital rights management system can be a separate system, a part of the operating systems of the portable digital media playback apparatus, a part of the operating system of a computer executing the media management software for the portable apparatus, a part of the media management software on the computer or on the portable apparatus, or combinations thereof. It can also exist and be executed on the content-provider server.

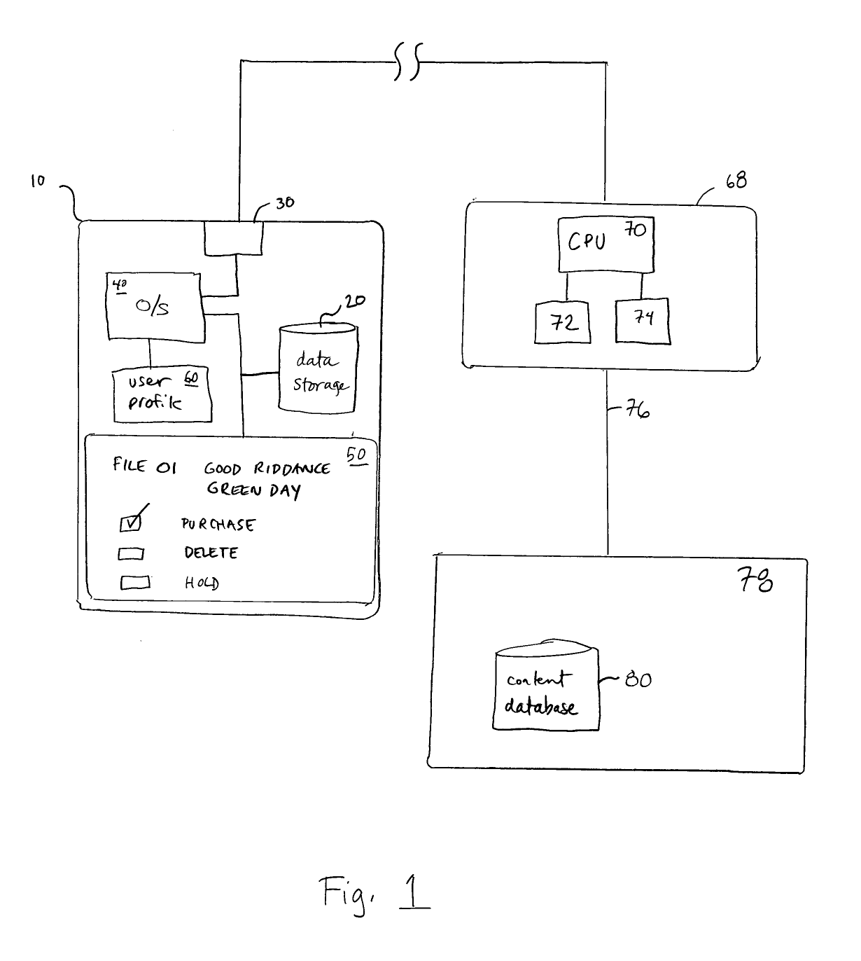

According to a preferred embodiment of the present invention, there is a portable digital media playback apparatus 10 shown in FIG. 1. The playback apparatus 10 has a massive storage device 20 which may be flash memory or a miniature hard drive, or some other space-efficient massive storage device capable of storing at least about 1 Gegabyte of data. The playback apparatus 10 has a communications port 30 which allows the playback device to communicate with external devices such as other computers or other portable devices. The communications port can effect these communications with external devices through hard-wired connections such as USB, Firewire, telephone cable, cable television line, and Ethernet cable. The communications port can also use wireless technology such as Bluetooth, 802.11g or infrared technology. The massive storage device 20 is in communication with a processor on the playback device 10 that is instructed by a portable device operating system 40. The operating system 40 can be, e.g., Apple's iPod portable music player proprietary operating system, or something similar. When the first iPod was released in 2001, its software's “About” section listed PortalPlayer, a company that offers platform suites for computer and consumer electronics manufacturers developing portable digital entertainment devices. A small company called Pixo was also credited, whose focus was on developing a wireless software platform and services for phone manufacturers. The Pixo software platform (Pixo Platform) included the Pixo Platform Applications, Pixo User Interface Builder, Pixo Application Framework, Pixo Toolbox, Pixo Kernel, Pixo Partner Applications, Pixo Internet Microbrowser, and so on.

The iPod uses PortalPlayer's “Digital Media Platform”, which is marketed as a turn-key solution as it includes System-On-Chip integrated circuits (ICs), a customizable firmware suite, integrated third party services, PC software, and so on. The iPod uses PortalPlayer's PP50xx chip, which contains two ARM7TDMI microprocessor cores. The iPod's embedded operating system, including its encoding and decoding components, also come from PortalPlayer.

Pixo's software, particularly the Toolbox, provided the foundation on which the iPod's user-interface was designed and implemented by Apple. The Pixo Toolbox included modules for memory management, low-level graphics such as bitmaps, boxes, lines, and text, Unicode, collection classes, resource database, and standard libraries. Pixo provided a range of data applications too, such as Address Book, Calculator, Calendar, Email, Graphical World Clock, Memo Maker, Todo List, and PC Synchronization.

Other examples of portable playback apparatus operating systems are the operating systems found in, e.g., Palm handheld PDAs, Treo and Blackberry hand sets for telephony including e-mail.

According to this embodiment of the present invention, the operating system 40 should be able to manage data storage functions, including the ability to place files into storage, recall files from storage and delete files from storage, as well as to manage the power functions of the portable device 10. In addition, the operating system should also facilitate communications to and from the communications port 30. The operating system 40 also should include instruction sets that enable it to create a user interface 50 such as, for example, the one shown in FIG. 1. In this embodiment, this user interface is graphical in nature and would be shown on a display screen of some kind familiar to those of ordinary skill in the art. The user would be able to navigate the operating system through the user interfaces shown on the display and in some circumstances with actual input devices such as buttons or keys. Typical tasks shown on the user interface, e.g., display screen, would be to select a digital media file from the library, to indicate through a tag or check or highlight, the user's interest in purchasing or renting the chosen file; or an instruction to delete one or more digital media files on the portable playback apparatus. The user interface may also provide the ability for the user to rate a digital media file that she has previewed. The user interface may use, for example, a scale of one (1) as the worst to five (5) as the best. These examples are intended to be illustrative and not limiting as to the configuration and operation of the user interface. It is also possible that the user interface could be voice-driven through commonly available speech synthesis and recognition software, rather than be a graphical user interface. It is also possible that the user interface could also be a combination of graphical presentations and voice-driven.

In this embodiment, also present on the portable playback apparatus 10 is a user profile 60. In one embodiment, the user profile contains data related to the user's selections of digital media files to preview, to purchase, to delete or to hold for additional usage. These activities are given codes that relate a particular activity to a digital media file present on the device. The user profile 60 may also contain personal information or demographic information about the user such as e-mail address, name, user name, age, income, sex and the like. The user profile may also contain information about ratings assigned to the various digital media files by the user in response to a preview event. As discussed more fully below, the user profile may be used by a content provider to recommend digital media files to be loaded on the portable playback apparatus by comparing the user profile with characteristic data about additional digital files that the content provider wants to push down to the user to entice sales. If there is a minimum set of matches, then the content provider will direct recommendations to the user of additional digital media file for preview.

There are many commercial customer relations management software products available to use to capture user activity on the portable playback device and to match this activity against digital media available for sale and rental to provide recommendations for additional digital media products to preview. Among some of the most widely used programs and services are Kana Software (Menlo Park, Calif. 94025), www.kana.com; Coremetrics, Inc. (San Mateo, Calif. 94404), www.coremetrics.com; and Mercado Software (Pleasanton, Calif. 94588), www.mercado.com. Some additional programs/services for performing the functions associated with the collection of data into a user profile and the use of that data for purposes of making user-specific recommendations are available at www.clicktracks.com; www.opentracker.net; and, www.mediaplex.com. Applicant also hereby incorporates by reference those portions of U.S. Pat. No. 5,963,916 that relate to the tracking of user activities on the content provider web site and storing records of those activities in association with the user identification.

In addition, the user profile data from one user can be aggregated by the content provider to compile marketing data for sale to digital media market participants. The provision of this aggregate market research data helps to generate additional revenues from operation of the portable device and/or related Internet sites.

In an alternative embodiment, the user profile is not kept on the playback device. Instead, the aggregate of the user's activities are transferred from the playback device to the separate computer where some determination is made of the user's actions to be captured into a user's profile. This user's profile data is then compared with data characteristic of additional digital media files available for preview. Using parameters determined by the content provider or his agent, the user file is used to create a list of digital media files for preview to be recommended to the user. This list then gets passed to the portable playback apparatus in the form of additional digital media files for preview, optionally with restricted digital rights that would provide for deletion after a particular amount of time or number of preview events.

In another embodiment, the user profile is created at the contact provider server by extracting information from the user interactions such as, for example, purchase, delete, hold commands, user's ratings of the digital media file, and/or personal information such as e-mail address, sex, income, musical preference, etc. In much the same way as user profiles created on the portable device and created on the separate computer, are used to recommend additional digital media available for sale or rental, the user profile created at the content provider server.

Because current portable (i.e. handheld) playback devices are not usually fully enabled with robust operating systems, another component of the system may be a separate computer that has a CPU 70, digital rights management database 72, a user profile database 74 and communications port 76 that can communicate with the portable playback apparatus 10 and to a content server 78 with digital files database 80. This server device, and possibly separate data storage, may be connected to the separate computer 76 through the Internet, but it may also be some sort of other network link, such as for example LAN/Ethernet. In the preferred embodiment, the separate computer is designed to operate as a portal or go-between the portable device and the content provider. The separate computer can be the user's personal computer running digital media management software, optionally including a digital rights management system. In the preferred embodiment, the separate computer would operate in substantially the same way as does the personal computer in the current use of iTunes and/or the iPod. In other words, the music library or video library is maintained and managed on the separate personal computer and then the portable device is “synched” or synchronized with the state of the digital media files or the personal computer.

The separate computer may also be an in-store device provided as a retail outlet for content to be loaded on the portable device. In essence, it is a “digital filling station” or an ATM machine for music The user can attach the portable device to the retail computer to upload selections, download purchases or rentals and to receive additional digital media files for preview.

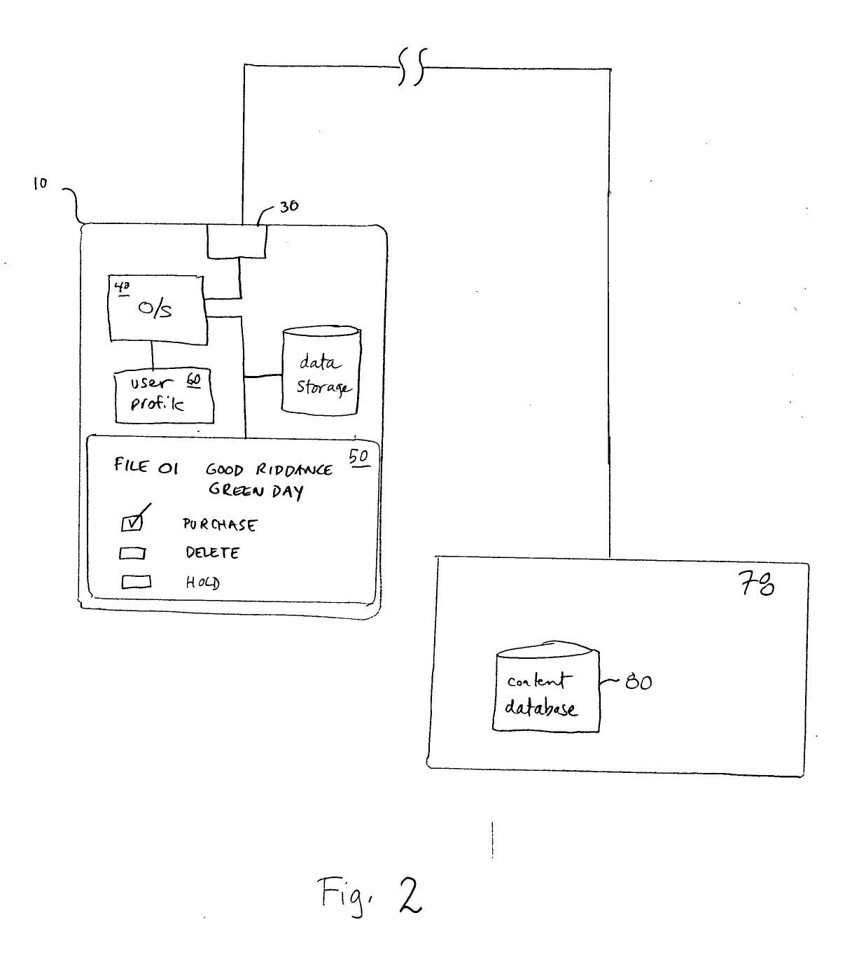

It is also part of the present invention that the separate computer can be eliminated as part of the system as shown in FIG. 2. So, for example, if the portable device has Internet browsing capability, then digital media files can be uploaded or downloaded to a content provider server, thereby eliminating the need for the intermediate computer. In order for this configuration to be effective, the portable device should include at a minimum, digital media management software and Internet browsing software.

According to the preferred embodiment shown in FIG. 1, the portable digital media playback apparatus 10 is preloaded with digital media files for preview by the user. The preloading can be done as part of the manufacturing process. It can also be done by a reseller who wants to provide a device full of digital media files for preview when the user buys the playback device. It can also be done at the point of sale of the playback device. The purpose of preloading digital media files is to utilize the massive storage present on the playback device as away in which to drive sales of digital media products.

In one embodiment of the invention, the user/purchaser can specify particular types of digital media files to be loaded on to the portable device prior to, or at the time of purchase. For example, a user may order a portable device online and specify that it be preloaded with digital media files for preview comprising, e.g., rock and pop music, or he may specify DVD preview files in the “Action” genre. In addition to online or telephone pre-ordering, the user and reseller may provide for the preloading to occur at a retail or public location where the portable device can be hooked up to the content server and rapidly loaded with large number of digital media files for preview. In addition, the device may be rapidly loaded with content from files stored on SD drives that may be inserted into the portable playback device, through the communications port 30, or some other slot or physical connectivity.

In addition to the digital media files for preview, the portable device may also be loaded with other content related to digital media such as CD/album cover art, liner notes, reviews and other materials descriptive of the products. It is also expected that the content providers and/or resellers will want to also include advertisements in the data downloaded to the portable device. It is possible that advertisers will team up with content providers so that the user obtains some type of premium (a free digital media file) in return for allowing the advertiser to download her advertisement to the user's portable device. It is also within the scope of this invention that the advertiser will be able to have access to the user profile so that contextual advertising may be pushed down to the user based upon the user's activities on the portable device in interacting with the pre-loaded files.

When preloaded, the digital media files for preview can be the complete digital file available for sale with limited usage rights (for example, 14 days from loading the file will be deleted, or after 5 playbacks of the file, the file will be deleted.) The digital media file available for preview may also be a reduced quality version of the digital file available for purchase or rental, optionally with limited usage rights. Moreover, the preloaded digital media files may be a temporal portion of the entire product available for sale or purchase. So, e.g., it would be possible to preload the device with a large number of digital media files (e.g. 128 Kb) that were 30 second portions of, e.g., audio songs. The purpose of this scheme of preloading the device is to provide the user with a large number of digital media files to preview as a prelude to purchase or rental of the digital media.

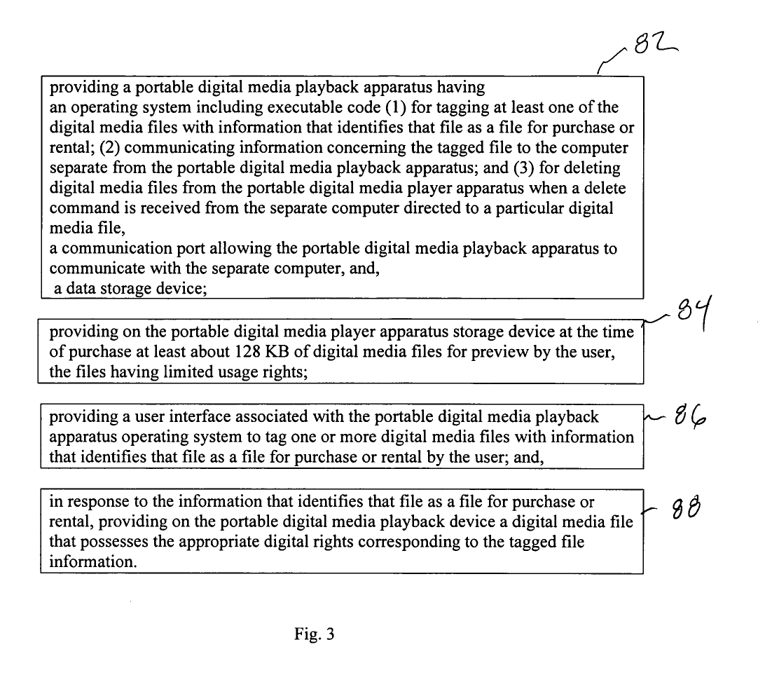

The concept here is to provide large numbers of digital media files pre-loaded on devices so that users can preview the items, rate them, indicate a purchase or rental selection and delete those that the user wants to delete. As shown in FIG. 3, these user activities are performed using the user interface on the portable device 86. When the portable device is subsequently synchronized with the media library on the separate computer 70, the user's selections, deletions etc. are uploaded to the separate computer by the playback apparatus operating system and communications port, and then the digital media files tagged by the user of the portable device to be purchased or rented are obtained either from the content server 80, or the CPU 70 which has previously obtained the digital media file from the content server 80. See box 88 in FIG. 3. The files that the user has marked for deletion are also deleted from the portable device. In certain embodiments, other digital media files are deleted from the portable device because the associated digital rights have expired. So, for example, the device may be preloaded with digital media files whose digital rights have been set so that after five (5) previews, the digital rights expire and the user no longer has the ability to play back the digital media. In order to enable this capability, there are at least two alternative configurations. In the first, the operating system on the portable device has sufficient digital media management software and digital rights management systems on the portable device to allow for the deletion of digital media files on the portable device upon expiration or fulfillment of the digital rights, conditions imposed at the time of preloading or loading. Alternatively, these functions can be performed by the separate computer. When the portable device is synchronized with the separate computer, the separate computer digital media management software and digital rights management systems can effectuate the appropriate file deletions on the portable device.

Another option that the user may be provided is to extend the digital rights on the portable device so that the user may preview the preloaded digital media file at some future point. Digital rights management software may be present on the CPU 70 and the content server 78, or both. There is some aspect of digital rights management software on the portable device that keeps track of either the time that a file has been on the device or the number of times it has been played. Examples of digital rights management systems that are capable of performing the functions just described can be found in, e.g., Apple's iTunes 6.0 and earlier versions. Other examples include U.S. patent application Ser. No. 10/703,149, published as Pub. No. 2005/0038753; U.S. patent application Ser. No. 09/773,716, published as Pub. No. 2002/0104019 A1; U.S. patent application Ser. No. 10/300,198, published as Pub. No. 2004/0098341; and, U.S. patent application Ser. No. 09/895,900, published as Pub. No. 2002/0002541. The disclosures of these publications are incorporated by reference, as is the product documentation for iTunes software.

It is also recognized that the user of the portable playback apparatus may seek and obtain digital media files from a variety of sources and possibly in a variety of file formats. It is desirable that the portable playback apparatus operating system be provided with the ability to import digital media files from a variety of sources and in a variety of formats, and still be able to “synch-up” with a single separate computer and where appropriate a single content provider. However, this is not a requirement of the invention.

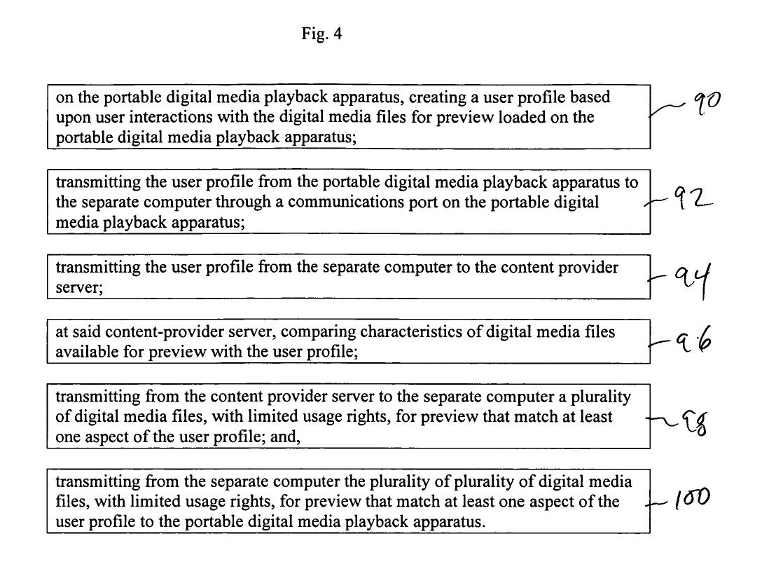

FIG. 4 describes a method of recommending additional digital media files for preview based upon user activities on the portable device. In the first step 90, a user profile is created on the portable device that tracks the user's interactions with the digital media files on the portable device. The user profile is transmitted (block 92) to the separate computer for subsequent transmission to the content provider server. See block 94. The content server then compares the user profile with additional files for pushing down to the user. The content provider sets appropriate criteria to select files for recommendation based upon common marketing principles and e.g., the available customer relations management software described above. See block 98. Ultimately, the recommended digital media files are pushed down to the user. See block 100.

While the present invention has been described with reference to specific embodiments, which are intended to illustrate and not to limit, those of ordinary skill in the art will recognize that certain changes and modifications may be made to the above-described embodiments without departing from the spirit of the invention and scope of the appended claims.

I claim:

1. A portable digital media playback apparatus having a large number of preloaded digital media files for preview by a user, the apparatus comprising:
(A) an operating system for operating the portable digital media playback apparatus, the operating system comprising executable software code for
(1) tagging at least one preloaded digital media file with information that identifies that file as a file for purchase or rental by the user;
(2) communicating the information concerning the tagged file to a computer separate from the portable digital media playback apparatus; and
(3) deleting digital media files from the portable digital media playback apparatus when a delete command is received from the separate computer for a particular digital media file;
(B) a communication port allowing the portable digital media playback apparatus to communicate with the separate computer;
(C) a data storage device preloaded at the time of purchase with at least about 128 KB of digital media files for preview by the user, the digital media files having limited usage rights; and,
(D) a user interface associated with the portable digital media playback apparatus operating system to direct the operating system to tag one or more digital media files with information that identifies that file as a file for purchase or rental by the user.

2. The apparatus according to claim 1, wherein the preloaded digital media files comprise at least about 75% of the storage capacity of the portable digital media playback apparatus data storage device.

3. The apparatus according to claim 2, wherein the preloaded digital media files comprise at least about 50% of the storage capacity of the portable digital media playback apparatus data storage device.

4. The apparatus according to claim 3, wherein the preloaded digital media files comprise at least about 25% of the storage capacity of the portable digital media playback apparatus data storage device.

5. The apparatus according to claim 1, further comprising,
a user interface allowing the user to rate the digital medial file; and
a ratings file associated with the portable digital media playback apparatus operating system for storing the ratings information for a particular digital media file.

6. The apparatus according to claim 5, wherein the operating system provides a rating system having a numerical value from 1 to 5.

7. The apparatus according to claim 1, wherein the portable digital media playback apparatus operating system includes digital rights management instructions that manage the usage rights of the preloaded digital media files and deletes untagged preloaded digital media files according to the corresponding usage right of that preloaded digital media file.

8. A method for providing and managing large numbers of digital media files on a portable digital media playback apparatus for preview and purchase or rental by a user, for use in conjunction with a computer separate from the potable digital media playback apparatus, the method comprising:
(A) providing a portable digital media playback apparatus having an operating system including executable code (1) for tagging at least one of the digital media files with information that identifies that file as a file for purchase or rental; (2) communicating information concerning the tagged file to the computer separate from the portable digital media playback apparatus; and (3) for deleting digital media files from the portable digital media player apparatus when a delete command is received from the separate computer directed to a particular digital media file,
a communication port allowing the portable digital media playback apparatus to communicate with the separate computer, and,
a data storage device;
(B) providing on the portable digital media player apparatus storage device at the time of purchase at least about 128 KB of digital media files for preview by the user, the files having limited usage rights;
(C) providing a user interface associated with the portable digital media playback apparatus operating system to tag one or more digital media files with information that identifies that file as a file for purchase or rental by the user; and,
(D) in response to the information that identifies that file as a file for purchase or rental, providing on the portable digital media playback device a digital media file that possesses the appropriate digital rights corresponding to the tagged file information.

9. The method of claim 8 further comprising the step of deleting untagged digital media files from the storage device of the portable digital media playback apparatus in response to a delete command issued by the separate computer.

10. The method of claim 9 further comprising the step of transmitting from the separate computer and storing in the storage device of the portable digital media playback apparatus new digital media files for preview by the user.

11. The method according to claim 8, wherein the preloaded digital media files comprise at least about 75% of the storage capacity of the portable digital media playback apparatus data storage device.

12. The method according to claim 8, wherein the preloaded digital media files comprise at least about 50% of the storage capacity of the portable digital media playback apparatus data storage device.

13. The method according to claim 8, wherein the preloaded digital media files comprise at least about 25% of the storage capacity of the portable digital media playback apparatus data storage device.

14. The method according to claim 8 further comprising the step of rating the preloaded digital media file after preview by the user,
wherein the portable digital media playback apparatus further includes a user interface that enables the user to rate the preloaded digital medial file, and includes a ratings file associated with the portable digital media playback apparatus operating system for storing the ratings information for a particular preloaded digital media file.

15. The method according to claim 14 further comprising the steps of
(1) transferring ratings information from the portable digital media playback apparatus ratings file to the separate computer; and
(2) using the separate computer, sending the ratings file to a web site.

16. The method according to claim 14 wherein a numerical value from 1 to 5 is provided for the rating step.

17. A portable digital media playback apparatus preloaded with a large number of digital media files at the time of purchase comprising:
storage media for storing preloaded digital media files for preview by a user;
a large number of preloaded digital media files stored in said storage media and available for preview by the user;
first executable software code for deleting at least one preloaded digital media file from the portable digital media playback apparatus storage media when a delete command is received;
second executable software code for tagging at least one preloaded digital media file with information that identifies the file as a file for purchase or rental by the user;
a first user interface allowing the user to issue delete commands to the first executable software code to delete preloaded digital media files from said storage media
a second user interface allowing the user, through operation of the second executable software code, to tag at least one preloaded digital media file with information that identifies that file as a file for purchase or rental by the user
a communications port between the portable digital media playback apparatus and the separate computer; and,
third executable software code for allowing the portable digital media playback apparatus to issue a request to the separate computer for the appropriate digital rights for the at least one digital media file corresponding to the information that identified the file as a file for purchase or rental.

18. In a system comprising a portable digital media playback apparatus loaded with a large number of digital media files for preview by a user of the portable digital media playback apparatus, a separate computer and a content provider server, a method for delivering recommended digital media files for preview on the portable digital media playback apparatus, the method comprising:
(a) on the portable digital media playback apparatus, creating a user profile based upon user interactions with the digital media files for preview loaded on the portable digital media playback apparatus;
(b) transmitting the user profile from the portable digital media playback apparatus to the separate computer through a communications port on the portable digital media playback apparatus;
(c) transmitting the user profile from the separate computer to the content provider server;
(d) at said content-provider server, comparing characteristics of digital media files available for preview with the user profile;
(e) transmitting from the content provider server to the separate computer a plurality of digital media files, with limited usage rights, for preview that match at least one aspect of the user profile; and,
(f) transmitting from the separate computer the plurality of plurality of digital media files, with limited usage rights, for preview that match at least one aspect of the user profile to the portable digital media playback apparatus.

19. The method according to claim 18 wherein the user profile also contains demographic information about the user.

20. The method according to claim 18 wherein the user profile contains rating information entered by the user comprising the user's rating of the digital media files that the user has already previewed.
